(19) United States
(12) Patent Application Publication
(10) Pub. No.: US 2024/0111490 A1
(43) Pub. Date: Apr. 4, 2024

(54) CURRENT INPUT ANALOG CONTENT ADDRESSABLE MEMORY

(71) Applicant: HEWLETT PACKARD ENTERPRISE DEVELOPMENT LP, Hoston, TX (US)

(72) Inventors: CATHERINE GRAVES, Milpitas, CA (US); GIACOMO PEDRETTI, Cernusco sul Naviglio (IT)

(21) Appl. No.: 17/953,595

(22) Filed: Sep. 27, 2022

(51) Int. Cl. G06F 7/544; G06F 17/16; G11C 15/04

(52) U.S. Cl. CPC G06F 7/5443; G06F 17/16; G11C 15/04

(57) ABSTRACT

Systems and methods are provided for employing a current input analog content addressable memory (CI-aCAM). The CI-aCAM is particularly structured as aCAM that allows the analog signal that is input into the aCAM cell to be received as current. A larger hardware architecture that combines two core analog compute circuits, namely a dot product engine (DPE) circuit for matrix multiplications and an aCAM circuit for search operations can also be realized using the disclosed CI-aCAM. For instance, a DPE circuit, which output current signals, can be directly connected with the input of a CI-aCAM, which is designed to receive current signals in a manner that eliminates conversion steps and circuits (e.g., analog to digital and current to voltage). By leveraging CI-aCAMs, a combined DPE-aCAM hardware architecture can be a realized as a substantially compact structure.

### BACKGROUND

A common computational action in the realm of complex computing is vector-matrix multiplication. Additionally, dense matrix computations, such as vector-matrix multiplication, dominate most machine learning algorithms. However, vector-matrix multiplication often overwhelming consumes the computation time and energy for many workloads, particularly in neural network algorithms and linear transforms (e.g., the Discrete Fourier Transform). An approach has begun to emerge, where memristor crossbars are leveraged attempting to improve this computational heavy-lifting associated with vector-matrix multiplication. By utilizing the natural current accumulation aspect of memristor crossbars, a Dot-Product Engine (DPE) can be designed as a high density, high power efficiency accelerator for approximate matrix-vector multiplication.

Content addressable memory (“CAM”) is a type of computing memory in which the stored data is not accessed by its location but rather by its content. A word, or “tag”, is input to the CAM, the CAM searches for the tag in its contents and, when found, the CAM returns the address of the location where the found contents reside. CAMs are powerful, efficient, and fast. However, CAMs are also relatively large, consume a lot of power, and are relatively expensive. These drawbacks limit their applicability to select applications in which their power, efficiency, and speed are sufficiently desirable to outweigh their size, cost, and power consumption. Nonetheless, there may be applications that directly benefit from combining the unique capabilities of DPEs and CAMs.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 depicts a diagram of an example of an analog content addressable memory (analog CAM), according to some embodiments.

FIG. 2A illustrates an example aCAM cell array, and can be comprised by aCAMs, such as the aCAM depicted in FIG. 1, according to some embodiments.

FIG. 2B is a conceptual diagram of an example range of voltages that can be implemented by the analog CAM cell, as shown in FIG. 2A, to perform search operations, according to some embodiments.

FIG. 3A depicts an example configuration for a circuit implementing an aCAM cell of FIG. 2A, according to some embodiments.

FIG. 3B is a conceptual diagram of a lower bound and an upper bound for search parameters that can be programed into the aCAM cell shown in FIG. 3A, according to some embodiments.

FIG. 4 depicts an example configuration for circuitry implementing a current input aCAM (CI-aCAM) circuit, according to some embodiments.

FIG. 5 depicts an example configuration for circuitry implementing a dot-product engine (DPE)-CAM circuit including the CI-aCAM circuit shown in FIG. 4, according to some embodiments.

FIG. 6 illustrates an example computing system that may be used to implement various features of embodiments described in the present disclosure.

The figures are not exhaustive and do not limit the present disclosure to the precise form disclosed.

### DETAILED DESCRIPTION

Content addressable memory (“CAM”) is a hardware that compares input patterns against its stored data. The memory that stores the data in the CAM also performs the search operation at the same location, eliminating the expensive data transfer between different units in conventional hardware. During the search, all the memory cells are operating in parallel, which leads to massive throughput with applications in real-time network traffic monitoring, access control lists (“ACL”), associative memories, etc.

CAMs can be implemented in technologies that permit the CAM to hold its contents even when power is lost or otherwise removed. Thus, a CAM's data “persists” and can act as what is known as a “non-volatile memory”. These technologies include, for instance, resistive switching memory (i.e. memristor), phase change memory, magnetoresistive memory, ferroelectric memory, some other resistive random-access memory device, or combinations of those technologies.

CAMs can be categorized as “binary” or “ternary”. A binary CAM (“BCAM”) operates on an input pattern containing binary bits of “0” and “1”. A ternary CAM (“TCAM”) operates on an input pattern (and stores data) containing not only binary bits of “0” and “1”, but also an “X” value. An “X” is sometimes referred to as a “don't care” or a “wildcard”. In a search on the input pattern in a TCAM, an “X” will return a match on either a “0” bit or a “1”. Thus, a search on the input pattern “10X1” will return a match for both “1001” and “1011”. Note that both BCAMs and TCAMS use and operate on binary values of “0” and “1”. CAMs are digital in that the data are stored in the CAM as binary values in a memory (e.g., SRAM, memristor, etc.) and the input patterns are represented by binarized logic ‘0’s and ‘1’s. Each memory cell in the CAM processes one value at a time (either 0/1 or 0/1/X), which limits the memory density and the power efficiency.

The present disclosure provides an analog CAM (“aCAM”) circuit, particularly a current input aCAM (CI-aCAM) that searches multilevel voltages and stores analog values in a nonvolatile memory (e.g., memristor). One analog cell can implement a function that is equivalent to multiple digital CAM cells, leading to significant advantages in area and power saving in implementing certain CAM-based functions. The aCAM circuit can be driven with standard multi-level digital values, or directly with analog signals, giving additional potential for increased functionality while removing the need for expensive analog-digital conversion. More particularly, an aCAM cell outputs a match when the analog input voltage matches a certain range that is defined by the aCAM cell.

Furthermore, the CI-aCAM is a particular implementation of an aCAM that allows the analog signal that is input into the aCAM cell to be received as a current. This distinct structure and function of the CI-aCAM can be advantageous building block that in utilized in a plethora of larger-scale applications. For example, a larger hardware architecture that combines two core analog compute circuits, namely a dot product engine (DPE) circuit for matrix multiplications and an aCAM circuit for search operations can be realized using the disclosed CI-aCAM. For instance, as described in detail herein, the CI-aCAM enables a connection of a DPE circuit, which output current signals, to be established directly with the input of a CI-aCAM, which is designed to receive current signals in a manner that eliminates expensive conversion steps and circuits (e.g., analog-to-digital, and current-to-voltage). Consequently, by leveraging CI-aCAMs, the resulting DPE-aCAM hardware architecture can be a substantially compact structure (e.g., only a single additional transistor is required to implement the CI-aCAM as compared with a voltage input aCAM).

Moreover, the DPE-aCAM hardware architecture has a wide-range of potential applications in the realm of neural networks and deep learning, such as Memory Augmented Neural Networks (MANNs), where similarity measures have to be performed after neural network evaluations are carried out. In these applications, including the functionality of the CI-aCAM within the hardware design of a DPE could achieve a direct mapping of the activation required for neural network output, thereby removing a conversion step also for traditional multi-layer neural networks. Leveraging CI-aCAMs, as disclosed herein, can also provide several hardware associated advantages, such as reduced area for more complex algorithms by eliminating the need for current to voltage conversion step circuits (e.g., implemented by a transimpedance amplifier when combining DPE and aCAM circuits, and reduced power consumption.

An aCAM, in accordance with the present disclosure, can match all values between a “high value” and a “low value”, or within a range, where the range includes non-binary values. These high and low values are set by programming memristors, and so are referred to as “R_{high}” and “R_{low}” herein. R_{high} and R_{low} set bounds of the range of values that may be stored in the cell such that the cell may store analog values. A memory cell in an aCAM may store any value between the value defined by R_{high} and the value defined by R_{low}. If R_{high}=Rₘₐₓ, where Rₘₐₓ is the maximum resistance of a memristor, and R_{low}=Rₘᵢₙ, where Rₘᵢₙ is the minimum resistance of a memristor, then the stored value is an “X”, as in a Ternary CAM. The number of equivalent digital cells or bits that can be stored in an analog CAM cell depends on the number of states the programmable resistor can be programmed to. To be able to encode the equivalent of n bits (i.e., n binary CAM/TCAM cells), the programmable resistor has 2ⁿ+1 states.

Thus, a memristor-based aCAM can search analog voltages. The memristor-based aCAM can also store analog values as the value(s) of resistance which fall in between R_{low} and R_{high} which are set by the multilevel resistance of the memristors. (A memristor-based aCAM may also search and store digital values.) One example of an aCAM includes a plurality of cells arranged in rows and columns. Each cell performs two analog comparisons: ‘greater than’ and ‘less than’ to the searched data line voltage at the same time, with significantly reduced processing time and energy consumption comparing to its digital counterpart. The aCAM can be driven with standard multi-level digital values or directly with analog signals in various examples. This provides additional potential for increased functionality when removing the need for expensive analog-digital conversion. The significant power saving of the proposed memristor aCAM enables the application of CAMs to more generalized computation and other novel application scenarios.

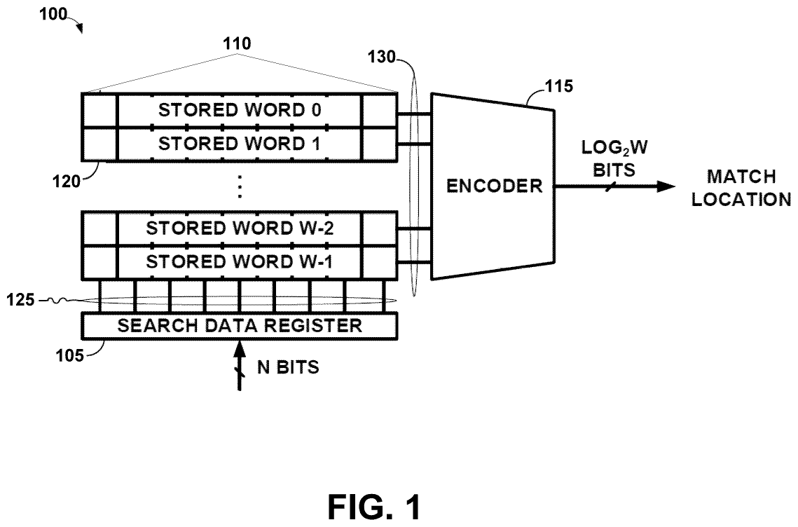

Turning now to the drawings, the aCAM disclosed herein may be used in digital applications to perform traditional TCAM functions and operations as well as in analog applications. FIG. 1, discussed further below, illustrates one particular example of a digital application of the aCAM.

Referring now to FIG. 1, an example of a CAM is illustrated. As a general description, CAMs are hardware that compare input patterns against its stored data. The memory that stores the data in the CAM also performs the search operation at the same location, eliminating expensive data transfer between different units in conventional hardware. During the search, all memory cells are operating in parallel, which can lead to massive throughput with applications in real-time network traffic monitoring, access control lists (ACL), associative memoires, and the like.

CAMs can be implemented in technologies that permit the CAM to hold its contents, even when power is lost or otherwise removed. Thus, a CAM's data “persists” and can act as a “non-volatile memory.” These technologies include, for instance, resistive switching memory (i.e., memristor), phase change memory, magnetoresistive memory, ferroelectric memory, some other resistive random-access memory device, or combinations of those technologies.

CAMs can be categorized as “binary” or “ternary.” A binary CAM (BCAM), operates on an input pattern containing binary bits of “0” and “1”. Additionally, a TCAM operates on an input pattern (and stores data) containing not only binary bits of “0” and “1”, but also an “X” value. An “X” is sometimes referred to as a “don't care” or a “wildcard”. In a search on the input pattern in a TCAM, an “X” will return a match on either a “0” bit or a “1” bit. Thus, a search on the pattern “10X1” will return a match for both “1001” and “1011”. Note that both BCAMs and TCAMs use and operate on binary values of “0” and “1”. CAMs are digital in that the data are stored in the CAM as binary values in a memory (e.g., SRAM, memristor, etc.) and the input patterns are represented by binarized logic ‘0’s and ‘1’s. Each memory cell in the CAM processes one value at a time (either 0/1 or 0/1/X), which limits the memory density and power efficiency.

Referring back to FIG. 1, an example of a CAM 100 that can implement the searching techniques and features disclosed herein is illustrated. The CAM 100, shown in the illustrated example, can be used in a digital application in which search patterns and the values stored in the CAM 100 are digital.

The CAM 100 can include a search data register 105, an analog memory cell array 110, and an encoder 115. The analog cell array 110 stores W “stored words” 0 through W-1. Each stored word is a pattern values, at least some of which may be analog values as described below. The search data register 105, in use, may be loaded with an analog or binary input pattern that can be searched from among the contents of analog cell array 110. The example of FIG. 1 operates on a binary input pattern as indicated by the ‘N bits’ going to the data line register. An example operating on an analog search pattern is discussed further below. Thus, instead of needing to store two bits of data in two columns as in the case for a digital CAM, one column of an analog CAM can encode four values.

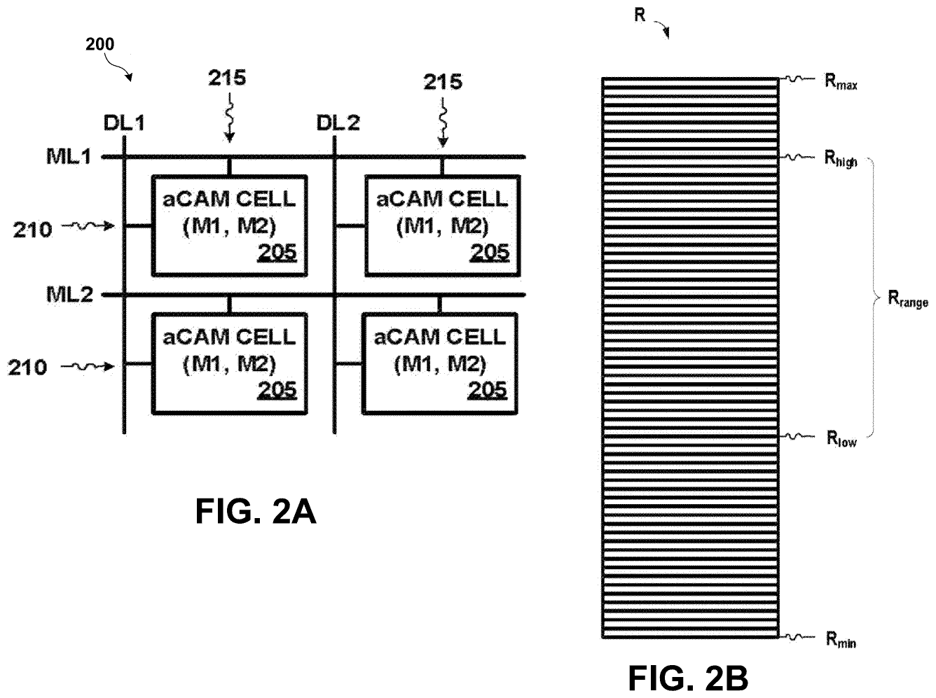

The analog cell array 110 includes a plurality of analog cells 120 (only one is indicated in FIG. 1) arranged in rows and columns. A configuration for the analog cells 120 within the CAM is more prominently shown and described in further detail in reference to FIG. 2. During a search, the analog input pattern loaded into the search data register 105 is communicated to the analog cell array 110 over a plurality of search lines 125. Some examples may use data lines in addition, or in lieu, of search lines. Each cell 120 then indicates whether a value of the analog input pattern is matched by a ranged of values contained in the cell (e.g., the range of values including non-binary values).

The indications of whether the cells contain matches are communicated to the encoder 115 over a plurality of match lines 130. Note that a match is found if the searched word (or pattern) matches the stored word within a single row. The match lines do not output the matches of individual cells, but whether the stored row word matches the searched data (row). More particularly, that match lines 130 are pre-charged high along rows, data is searches on search lines 125 (or data lines) along columns, and if a mismatch between searched and stored content occurs, the 130 discharges and goes low. If a match occurs, the match line 130 stays high.

The encoder 115 is a priority encoder that returns a match location with the analog cell array 110. Note that the encoder 115 may be omitted in some examples, particularly in examples in which multiple match locations are identified and desired. For instance, because the “wild card values may be included in the input pattern, multiple matches among the W stored words may be found. Some examples might wish to identify more than one, or even all, match locations and these examples would omit the encoder 115.

FIG. 2A illustrates selected portions of an analog cell array 200 of aCAMs, such as the aCAM 100 in FIG. 1, in one particular example. The aCAM cells 205 are arranged in rows 210 and columns 215 and are each individually searchable over the data lines DL1, DL2. Whether a match is found from data on DL1 and DL2 and the data stored in the rows by each aCAM cell's M1 and M2 programmed values is indicated over the match lines ML1, ML2. As those in the art having the benefit of this disclosure will appreciate, an analog cell array 200 will typically be larger in area has a 2×2 array. The precise size of an analog cell array will be implementation specific, for instance being an M×N array of aCAM cells (where M and N are greater than 2). The 2×2 portion depicted in FIG. 2A is shown for illustrative purposes and is not limiting.

Each aCAM cell 205 includes two memristors M1, M2 (not separately shown) that are used to define the range of values stored in the respective aCAM cell 205. FIG. 2B conceptually illustrates a resistance differential that may be used to set the stored analog value or range of the aCAM cells 205, in some examples. The total range of resistance R that may be implemented by both memristors M1 and M2 is defined by a maximum resistance Rₘₐₓ and a minimum resistance Rₘᵢₙ. The maximum resistance Rₘₐₓ and the minimum resistance Rₘᵢₙ are given by the materials properties of memristors. A range of resistance R_{range} is defined by R_{high} and R_{low}. R_{high} is determined by programming a value in M1 and R_{low} is determined by programming a value in M2. When an analog value is stored, the analog number is encoded in the cell via two resistance thresholds, a high and a low resistance threshold within which the analog value of the cell (or range value) resides. Several electronic circuits by which the aCAM cells 205 may be implemented will be discussed further below.

As discussed above, the present disclosure may encode more than three levels in a content addressable memory. In a memristor CAM, the information is ultimately mapped to resistance levels and there are 2ⁿ+1 distinct resistance levels between R_{low} and R_{high}. That is, R_{range}=R_{high}−R_{low} and includes 2ⁿ+1 distinct resistance levels, each distinct resistance level representing a different value. For example, where R_{high}≠R_{low} and R_{high}>R_{low}, then the aCAM cell 205 stores all levels between R_{low} and R_{high}. For another example, if R_{high}=Rₘₐₓ and R_{low}=Rₘᵢₙ, then the aCAM cell 205 stores an X=wild card value. For yet another example, if R_{high}=a resistance R₁ and R_{low}=R₁−delta where delta=(Rₘₐₓ−Rₘᵢₙ)/(2ⁿ), then the aCAM cell 205 stores the single level R₁.

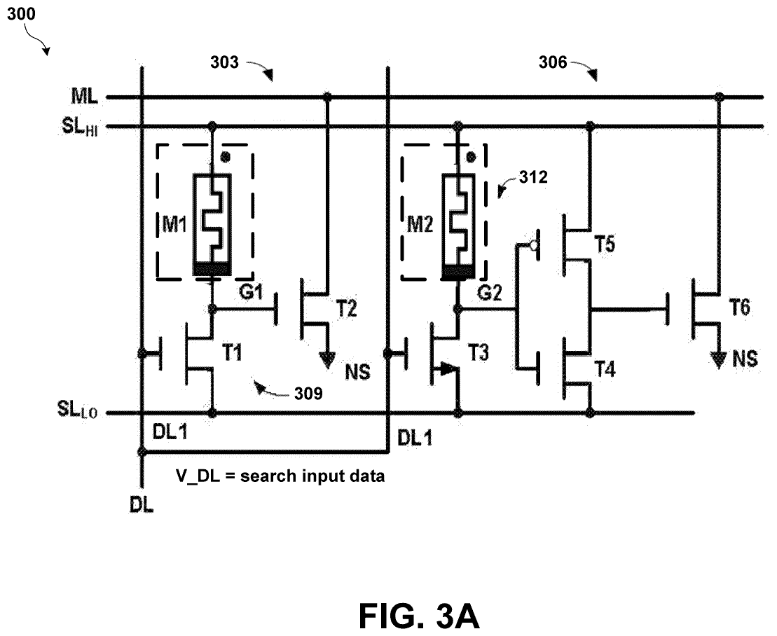

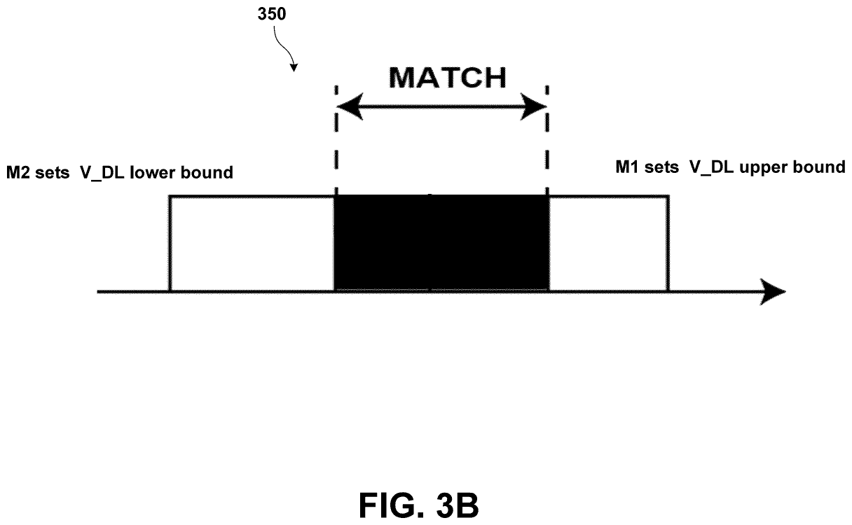

FIG. 3A depicts an electronic circuit implementing an aCAM cell 300 that may be used to implement the aCAM cells 205 of FIG. 2A in some examples. As a general description, the aCAM cell 300 acts as an “analog TCAM” cell that searches an analog voltage range. A Match Line (ML) is first pre-charged to a high voltage. An input to DL1 and DL2 is then applied, which will eventually discharge the ML if the input is out of the analog voltage range encoded in the aCAM cell. The matching analog voltage range is defined as the conductance of non-volatile memristors, where M1 defines the lower voltage bound and M2 defines the upper voltage bound.

The aCAM cell 300 includes a “low side” 306 and a “high side” 303, so-called because the memristor M2 and the memristor M1 are programmed to determine the values of R_{low} and R_{high}, respectively. The high side 303 includes a first transistor T1 and a first memristor M1. The first memristor M1, in conjunction with the first transistor T1, defines a first voltage divider 309 and, when programmed, defines a high value R_{high} of a range of values R_{range}. The high side 303 also includes a second transistor T2 that, in use, indicates whether a searched value matches the high value R_{high}. The low side 306 includes a third transistor T3 and the second memristor M2. The second memristor M2, in conjunction with the third transistor T3, defines a second voltage divider 312. When the second memristor M2 is programmed, the memristor M2 defines the low value R_{low} of the range of values R_{range}. The low side 306 also includes another transistor T6 that, in use, indicates whether the searched value matches the low value R_{low}.

The aCAM cell 300 also includes a match line ML, search lines SL_{HI}, SL_{LO} and data lines DL, DL1. As noted above, the memristor-transistor pairs M1/T1 and M2/T3 define a respective voltage divider 309, 312. The voltage dividers 309, 312 are used to encode R_{high} and R_{low} when the memristors M1, M2 are programmed. Thus, in this example, in each memristor-transistor pair M1/T1 and M2/T3, the analog search is implemented as the gate voltage of the transistor to create a variable-resistor divider with the memristors programmed to an analog (stored) value. In the example of FIG. 3A, the inputs can be tied together, so that T1/M1 and T3/M2 are equivalent in function, but T4/T5 form an inverter. Thus, the left side and right side are defining the high and low side independently, and the match line ML is high only when a voltage on the data line DL is within a range of voltages that are defined by M1 and M2 resistances. That is, the low side, being tied to T3/M2 has a node gate voltage that is inverted by the transistors T4, T5 in a manner that causes smaller input voltage values (e.g., data line DL input voltage is smaller than the threshold) to drive the ML low which is indicative of a “mismatch” (e.g., data line DL input value is smaller than the minimum voltage defined by R_{low}). For example, the match ML is pre-charged high along rows, data is searched on search lines lines SL_{HI}, SL_{LO} along columns, and if a mismatch between searched and stored content occurs, the match line ML discharges and goes low. If a match occurs, the match line ML stays high. Note that, although the T4/T5 inverter is in the low side 306 in the illustrated example, it may be implemented in the high side 303 in other examples.

More particularly, memristor M1 and transistor T1 form a voltage divider 309, in which M1 is a memristor with tunable non-volatile resistance and T1 is a transistor whose resistance increases with the input voltage on the data line DL. Therefore, there exists a threshold voltage, dependent on the M1 resistance, that when the data line DL input voltage is smaller than the threshold, the pull-down transistor T2 turns on which pulls down the match line ML yielding a ‘mismatch’ result. Similarly, memristor M2 and transistor T3 form another voltage divider 312, and the internal voltage node is inverted by the transistors T4, T5 before applying to another pull-down transistor T6. As a result, with properly programmed resistances in the memristors M1, M2, the aCAM cell 300 keeps the match line ML high only when the voltage on the data line DL is within a certain range defined by M1 and M2 resistances.

Still referring to FIG. 3A, the search result is therefore sensed as the voltage level on the ML, which is pulled down (i.e., decreased) when the gate voltage of the pull-down transistor T1 and/or T3 exceeds its threshold voltage (Vth). Voltage on G1 (V_{G1}) decreases with V_{DL}. Therefore, a lower bound voltage (Vₗₒ) exists, which is configurable by the corresponding memristor conductance, that when the V_{DL} is smaller than Vₗₒ, V_{G1} is larger than the Vₜₕ of the pull-down transistor, causing the match line ML to be pulled down for a ‘mismatch’ result. Similarly, voltage on G2 (V_{G2}) increases with V_{DL}, and therefore the upper bound voltage is configured by another memristor conductance in the same aCAM cell 300. Combining the two parts, the search voltage upper and lower range (i.e. the search voltage range) is configured with the two memristor conductances in one aCAM cell.

The pre-charging of the match line ML can be initiated by enabling a pre-charging peripheral (not shown in FIG. 3A). The data lines DL are asserted in conjunction with the match line ML pre-charge while SL_{HI} is kept low. The search is started by asserting SL_{HI}. A transient voltage response on the ML with a search range can be defined in the memristors. The search result sensed from the match line ML after initiating the search shows that the aCAM cell 300 outputs a match when the voltage on the data line DL falls within a predefined range defined by the memristor conductances given by G(M1) and G(M2) where conductance is the inverse of resistance. If a match occurs, the match line ML stays high outputting a voltage signal that is sensed by a voltage sensing peripheral (not shown in FIG. 3A). The gate voltage V_{G1} at G1 in FIG. 3A of the pull-down transistor T2 drops to a voltage below its threshold with increasing data line DL voltage. The gate voltage V_{G2} at G2 in FIG. 3A of the pull-down transistor T6 increases to a voltage above its threshold with increasing data line DL voltage. The cut-off data line DL voltage for a lower and upper bound of a matched search increases with the corresponding memristor conductance.

An aCAM cell can search analog voltages and stores analog values as the value(s) which fall in within an analog voltage range. FIG. 3B is a conceptual diagram, in order to depict that M2 sets an analog value that defines the lower bound (V_DL_{lowerbound}) portion of the search parameters, and M1 sets the analog value that defines the upper bound (V_DL_{upperbound}) portion of the search parameters that can be programed into the aCAM cell shown in FIG. 3A. In the example, the shaded portion of bar 350 represents a width, which is the range of voltages that are encoded in aCAM cell. As described above, the width (represented by the shaded portion of bar 350) can include a range of analog voltage values, having an upper limit of an upper voltage level that is set by M1. Also, the width (represented by the shaded portion of bar 350) can include a range of analog voltage values, having a lower limit that is defined by a lower voltage level that is set by M2. Accordingly, for a search against the analog value stored by aCAM cell (shown in FIG. 2A) to result in a match, the voltage (V_DL) applied on data line DL (representing the search input data) must be a voltage value that falls within the range of voltage values defined by these limits (e.g., V_DL_{lowerbound}≤V_DL≤V_DL_{upperbound} or inside of the shaded portion of bar 350).

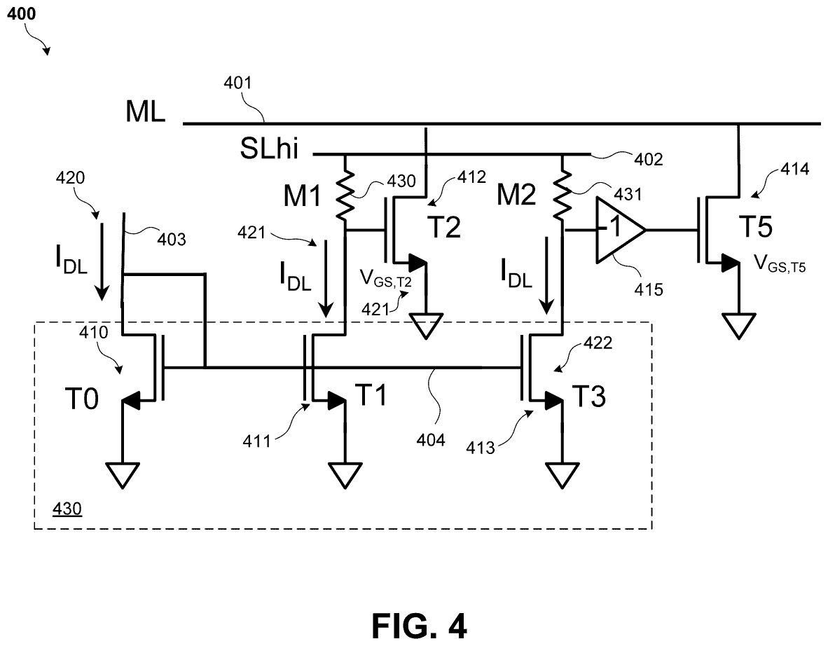

Referring now to FIG. 4, an example configuration for a circuit 400, which implements the disclosed current input aCAM (CI-aCAM) is depicted. The CI-aCAM circuit 400 implements an aCAM cell (also referred to herein as a CI-aCAM cell) that functions similarly to the voltage input aCAM circuit (shown in FIG. 3A). Therefore, the CI-aCAM circuit 400 can be described as an “CI-aCAM cell” that searches an analog current range.

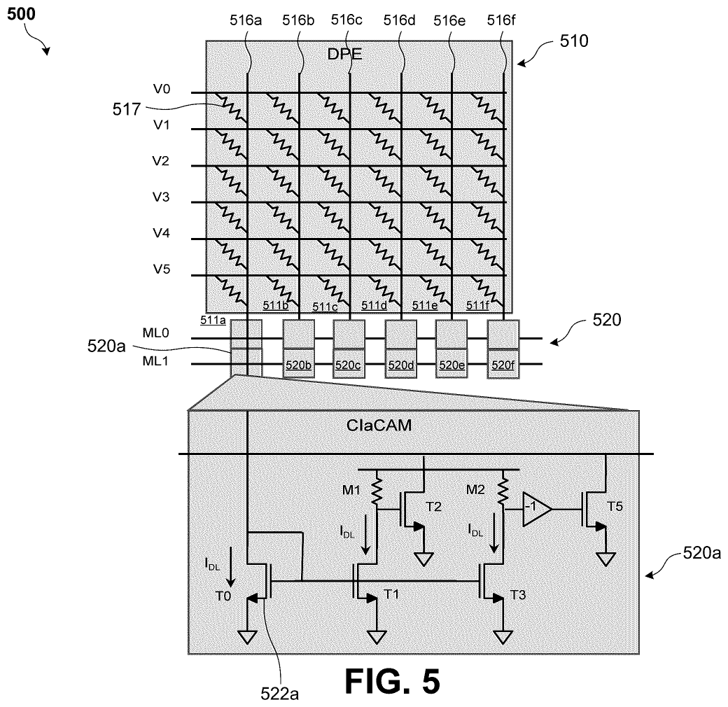

In contrast to the voltage input aCAM implementation (as previously discussed above in reference to FIG. 3A and FIG. 3B) which accepts a voltage signal as input, the CI-aCAM circuit 400 is distinctly configured to enable receiving a current signal as an input signal, while maintaining the same searchable aCAM functionality. Thus, by employing the CI-aCAM circuitry 400 which supports current inputs, a direct connection of a DPE output, which is commonly a current signal, can be fed directly into the input of the CI-aCAM as a current signal (e.g., without an ancillary conversion from current-to-voltage). Accordingly, the CI-aCAM circuit 400 can be leveraged in a wide range of applications where it may be optimal for an aCAM to receive search input data, in the form of an input signal, that is conveyed as a current signal. One such application for the CI-aCAM circuit 400, as disclosed herein, is to realize a combined DPE-aCAM circuit structure, which is illustrated in FIG. 5.

Referring back to FIG. 4, the CI-aCAM circuit 400 can be generally described as including an additional transistor, shown as TO transistor 410, in comparison to the implementation of the voltage input aCAM (shown in FIG. 3A). Particularly, as seen in the example configuration of FIG. 4, the CI-aCAM circuit 400 comprises several components, including: TO transistor 410; T1 transistor 411; T2 transistor 412; T3 transistor 413; T5 transistor 414; diode 415; M1 memristor 430; and M2 memristor 431. The CI-aCAM circuit 400 also includes several lines, including: match line ML 401, search line SL_{HI} 402, and input data line I_{DL} 403 (also referred to herein as input line). An input signal, which conveys the input data (search input data), enters into the CI-aCAM circuit 400 as a current signal. For example, an I₀ current, which is a current signal propagating into the CI-aCAM 400 as the input signal, can be received by the input data line I_{DL} 403. As an operational example, the CI-aCAM circuit 400 can be employed in a MANN processing application, for instance as an element in the DPE-aCAM implementation described below in reference to FIG. 5. According to this example, the input data that is entered into the CI-aCAM circuit 400 (i.e., current signal I_{DL} 420) can represent one of the elements of a vector resulting from the matrix vector multiplication achieved with an DPE (e.g., a layer of a neural network, which is associate to other vectors stored in the CI-aCAM). Continuing with this example, given a DPE of size 100×100 and memristor with conductance programmable between 1 uS and 100uS, the input signal I_{DL} 420 (conveying the search input data) could be in the range 10uA-1 mA assuming a voltage input of the DPE equal to approximately 0.1 V.

As previously described, the analog search is implemented as the gate voltage of the transistor to create a variable-resistor divider with the memristors programmed to an analog (stored) value. For example, gate voltage of T2 transistor 412 can be represented, with respect to the current along the input line I_{DL} 403, mathematically as:

$${V}_{G S , T 2} = S {L}_{h i} - \frac{{I}_{D L}}{M 1} \qquad ( 1 )$$

The match line ML 401 is first pre-charged to a high voltage, for example approximately 1 V. The CI-aCAM circuit 400 is configured such that when the gate voltage at T2 transistor 412, shown as V_{GS,T2} 421, is high (e.g., pull-down T2 transistor 412 turns on), which is caused when current I_{DL} 420 is low, it will eventually discharge the match line ML 401 which represent a “mismatch” (with respect to a match between the analog value stored by the CI-aCAM circuit 400 and the search input data). In operation, a current signal is received as input, namely as the input signal, into the CI-aCAM circuit 400 on input data line I_{DL} 403, illustrated as current I_{DL} 420. In other words, current I_{DL} 420 represents the search input data for the CI-aCAM cell implemented by CI-aCAM circuit 400, which is received via the input line 403. This current signal I_{DL} 420 then flows into a “current mirror” circuit block 430 (indicated by dashed lined box) that is formed by TO transistor 410, T1 transistor 411, and T3 transistor 413.

As referred to herein, a current mirror is circuitry that is designed to copy or “mirror” a current through one active device by controlling the current in another active device of a circuit, keeping the output current constant regardless of loading. In the illustrated configuration of FIG. 4, three transistors comprise the “current mirror” circuit block 430, namely TO transistor 410, T1 transistor 411, and T3 transistor 413. As seen, TO transistor 410 has its gate terminal and drain terminal connected. Furthermore, the gate terminal of TO transistor 410 is coupled to the gate terminal of T1 transistor 411, and the gate terminal of T3 transistor 413 is coupled to the gate terminal of T1 transistor 411. Each of the transistors, TO transistor 410, T1 transistor 411, and T3 transistor 413, have the respective source terminals coupled to ground. The transistors, TO transistor 410, T1 transistor 411, and T3 transistor 413 being coupled to each other by their respective gate terminals forms the “current mirror” circuit block 430. As a general description, the “current mirror” circuit block 430 causes a current signal propagating through TO transistor 410 to be “copied” across T1 transistor 411 and T3 transistor 413. Restated, this “current mirror” circuit block 430 of the CI-aCAM circuit 400 includes circuitry for receiving a mirrored current from the TO transistor 410. In terms of the operation of the “current mirror” circuit block 430, the gate-source junction of TO transistor 410 acts like a diode because the drain and gate are connected together. The current, shown as current signal I_{DL} 420, entering into the drain terminal of TO transistor 410 causes a given voltage built up across the gate-source junction of TO transistor 410. As a result, the gate-source voltages on TO transistor 410, T1 transistor 411, and T3 transistor 413 are the same. Based on the fundamental relationship that transistors (e.g., same size, at the same temperature) having the same gate voltage V_{GS} will have the same drain current, the same gate-source voltages thereby causes the drain current of T1 transistor 411 and the drain current of T3 transistor 413 to exactly mirror the drain current of TO transistor 410 (assuming that both transistors are accurately matched), which is I_{DL} 420. Therefore, the current flowing into TO transistor 410 is mirrored into T1 transistor 411 and T3 transistor 413. In the example configuration of FIG. 4, the transistors, TO transistor 410, T1 transistor 411, and T3 transistor 413, of the “current mirror” circuit block 430 are shown as Field-Effect Transistors (FETs). Nonetheless, this configuration is not intended to be limiting and other transistor devices can be employed, such as Bipolar Junction Transistors (BJTs), Junction-Gate Field-Effect Transistors (JFETs), and Metal Oxide Semiconductor Field-Effect Transistors (MOSFETs). Additionally, in some embodiments, the “current mirror” circuit block 430 may use more than three transistors and include additional devices in its configuration to enable the level of performance to be improved. Thus, due to the aforementioned mirroring effect of the “current mirror” circuit block 430, the current flowing into T1 transistor 411 and T3 transistor 413 are mirrored copies, that are equal to the current flowing into TO, which is depicted as current I_{DL} 420.

As a general description, the CI-aCAM circuit 400 is configured such that the gate voltage at the T2 transistor 412 (i.e., voltage V_{GS,T2} 421) decreases as the current I_{DL} 420 increases, and conversely the gate voltage at the T2 transistor 412 (i.e., voltage V_{GS,T2} 421) increases as the current I_{DL} 420 decreases. Therefore, in the case where the current I_{DL} 420 is a substantially small value, for example approximately 0.1 μA, (the current I_{DL} 420 is also mirrored at T2 transistor 412) causes the V_{GS,T2} 421 to be substantially high, for example approximately 1 V. A “mismatch” condition is met in the search operation, as the ML 401 is discharged. Other examples of a small value associated with the current I_{DL} 420 can be a current signal that is within the range of 0.05 μA and 0.5 μA. Other examples of a high value associated with the gate voltage V_{GS,T2} 421 can be a voltage signal that is within the range of 1 V and 10 V. In contrast, when current I_{DL} 420 is substantially large, for instance approximately 50 μA, at the input, a “match” condition is met. In particular, this “match” condition is not modulated by the memristors 430, 431. To reach this “match” condition, when the current I_{DL} 420 is a substantially high value, and the V_{GS,T2} 421 is a substantially low value, for example approximately 0 V, (e.g., pull-down T2 transistor 412 turns off), then the match line ML 401 stays charged. Other examples of a large value associated with the current I_{DL} 420 can be a current signal that is within the range of 25 μA and 75 μA. Other examples of a low value associated with the gate voltage V_{GS,T2} 421 can be a voltage signal that is within the range of 0 V and 0.05 V.

Additionally, the CI-aCAM circuit 400 is configured to enable the search condition to be modulated by the memristors 430, 431. In this case, the CI-aCAM circuit 400 operates similar to the voltage input aCAM as described in detail above in reference to FIG. 3A. That is, the CI-aCAM circuit 400 searches an analog voltage range that is set by the conductances of M1 memristor 430 and M2 memristor 431. In this embodiment, if the input current (search input data) I_{DL} 420 corresponds to a voltage that is out of the analog voltage range that is encoded in the CI-aCAM cell, then there is a “mismatch.” For each memristor-transistor pair M1/T1 and M2/T3, the analog search is implemented as the gate voltage of the transistor to create a variable-resistor divider with the memristors programmed to an analog (stored) value. The matching analog voltage range is defined as the programmed conductance of non-volatile memristors 430, 431, where M2 memristor 431 defines the lower voltage bound and M1 memristor 430 defines the upper voltage bound. The memristor conductances of M1 memristor 430 and M2 memristor 431 can be programmed via dedicated inputs at the gate terminals of T1 transistor 411 and T3 transistor 413 (not shown in FIG. 4). The search result can be sensed from the match line ML 401 after initiating the search, where that CI-aCAM cell outputs a match when the current I_{DL} 420 on the input data line I_{DL} 403 has an associated voltage that falls within a predefined range defined by the memristor conductances given by G(M1) and G(M2). For example, sensing a low voltage on match line ML 401 corresponds to a mismatch, while sensing a high voltage on the match line ML 401 corresponds to a match. As previously described, the match line ML 401 can be pre-charged for fast sensing. In some embodiments, sensing a search result on the match line ML 401 involves measuring the current of the match line ML 401 after a given time. For instance, the voltage on the match line ML 401 will discharge in case of a mismatch, where the lowered and/or discharged voltage results in a small current being sensed on the match line ML 401.

The gate voltage V_{Gs,T2} 421 of the pull-down T2 transistor 412 drops to a voltage below its threshold with increasing data line DL current I_{DL} 420. The gate voltage V_{GS,T5} 422 of the pull-down transistor T5 increases to a voltage above its threshold with increasing data line DL current I_{DL} 420. Accordingly, for a search against the analog value stored by the CI-aCAM cell implemented by circuit 400 to result in a match (modified by the memristor conductances), the current I_{DL} 420 applied to the input data line I_{DL} 403 (representing the search input data) must be associated with a current value that falls within the range of current values defined by the high limit set by M1 memristor 430 and the low limit set by M2 memristor 431 (e.g., I_DL_{lowerbound}≤I_DL_{upperbound}). As the M1 memristor 430 and M2 memristor 431 set the R_{high} limit and the R_{low} limit respectively, which define bounds of the range of resistance values that may be stored in CI-aCAM cell (i.e., analog values stored in the CI-aCAM), this defined resistance range also corresponds to defining a current input range [I_DL_{lowerbound}, I_DL_{upperbound}]. Thus, the limits set by M1 memristor 430 and M2 memristor 431 also serves as a defined range of current values (corresponding to the range of resistance values) which enables the CI-aCAM cell implemented by circuit 400 to return a match on the match line ML 401 when the input signal, current I_{DL} 420, falls within this range of current values.

FIG. 5 depicts an example of a conceptual configuration for a DPE-aCAM circuit 500 that can be constructed using the CI-aCAM circuitry (shown in FIG. 4), as disclosed herein. As previously described, the CI-aCAM circuitry has distinct capabilities that may be leveraged in numerous applications, and the DPE-aCAM circuit 500 is one such application. Generally, the configuration of the DPE-aCAM circuit 500 can be described as two core analog compute circuit blocks that care coupled together, namely a circuit block implementing a DPE circuit 510 for performing for matrix multiplication and an additional circuit block implementing an CI-aCAM array circuit 520 for performing search operations based on the results of the matrix multiplication. There are new functionalities and optimizations that may be realized by connecting DPE outputs (shown in FIG. 5 as the outputs 511a-511f of the DPE circuit 510) to the input of an aCAM (shown in FIG. 5 as the inputs 521a-521f to respective CI-aCAMs 520a-520f). Accordingly, the DPE circuit 510 can output multiple current signals that convey results of the matrix multiplication that the circuit 510 performs. Subsequently, the CI-aCAM array circuit 520 receives these currents signals from the DPE circuit 510 as input signals, in a manner that allows the input signals (e.g., current signals) for the CI-aCAM array circuit 520 to also convey the results of the matrix multiplication that is performed by the DPE circuit 510. The CI-aCAM array circuit 520 generates output signals that correspond to multiple search operations that are based on the input signals, where the input signals are associated with the results of the matrix multiplication. For example, the DPE-aCAM circuit 500 can be used in a neural network application, where the DPE 510 is specifically employed to implement various feature extraction layers (via neural network fully connected layers), and then the extracted feature vectors can be input into the CI-aCAMs 520a-520f.

Memristors are devices that may be used as components in a wide range of electronic circuits, such as memories, switches, radio frequency circuits, and logic circuits and systems. FIG. 5 shows an example of an application for memristors, illustrated as a crossbar matrix forming the DPE 510. The crossbar matrix has multiple memristors 512 arranged therein. In some cases, the crossbar matrix of the DPE 510 can be a memory structure. Even further, the crossbar matrix 510 of the DPE 510 can be used in larger-scale systems, such as a DPE based neural network accelerators. In general, the memristor crossbar matrix of the DPE 510 can be used to implement hardware accelerators for calculating node values for neural networks. As an example, in a neural network processing accelerator, the memristor crossbar matrix of the DPE 510 may be programmed to calculate node values. Memory cells of the memristor crossbar matrix of the DPE 510 may be programmed according to a weight matrix. Driving input voltages mapped from an input vector through the memristor crossbar matrix of the DPE 510 may produce output current values, for example accumulating across each column 516a-516f, which in some instances may ultimately be converted to digital values that represent a matrix-vector multiply result. In other words, the memristor crossbar matrix of the DPE circuit 510 comprises a plurality of columns of output lines to collect all currents output from the resistive memory elements, where the collected currents on each of the columns 516a-516f equal a corresponding matrix multiplication value (or element of the vector result of the matrix multiplication). In this manner, accelerators can provide hardware calculations of node values for neural networks. In the illustrated example, the memristor crossbar matrix of the DPE 510 is configured to include contributions from each memristor 517 in the matrix. The use of memristors 517 at junctions or cross-points of the memristor crossbar matrix of the DPE 510 enables programming the resistance or conductance (G) at each such junction.

Employing memristors 517 to perform vector-matrix computations for neural network process has led to advancements in many metrics (with several order of magnitudes advantage) with respect to conventional processing, such as performance, power, and costs. As previously alluded to above, memristors 517 are often times at the core in many hardware designs for enabling matrix multiplication functionality for DPE based processors, such as the DPE 510.

Performing vector multiplication plus search operations can be implemented by the DPE-aCAM circuit 500 with enhanced efficiency, as the CI-aCAMs 520a-520f are leveraged in a manner that receives the outputs from the DPE 510 directly and without any additional processing delay that would otherwise be necessary with using voltage input aCAMs. Restated, by distinctly structuring the DPE-aCAM circuit 500 using CI-aCAMs 520a-520f, this eliminates an intermediate conversion step that would take place between the current signals that are output of DPE and the voltage signals that are required as input to aCAMs. Consequently, the disclosed DPE-aCAM circuit 500 could potentially accelerate different operations, such as memory augmented neural networks (MANN), and increase the capacity of the CI-aCAMs itself.

As illustrated in FIG. 5, the DPE-aCAM circuit 500 configuration includes: a DPE 510 section of the circuitry 500, which implements the matrix multiplication capabilities of the circuitry and is structured as a memristor crossbar; and an CI-aCAM array 520 section of the circuitry 500, which implements the searching capabilities of the circuitry and is implemented as a row of a plurality of individual CI-aCAM circuits 520a-520f. Each of the inputs 521a-521f, which independently corresponds to one of the CI-aCAM circuits 520a-520f, are coupled to a corresponding output 511a-511f from the DPE 510. In other words, each CI-aCAM circuit 520a-520f has their respective input 521a-521f coupled to the output 511a-511f from a column of the memristor crossbar implementing the matrix for the DPE 510. Thus, the current signal that is output from each respective column of the memristor crossbar from the DPE 510 as a result in a vector-matrix multiplication operation from outputs 511a-511f, can be fed directly as a current signal to be received by an input 521a-521f to the respectively coupled CI-aCAM circuits 520a-520f. As previously described, it is the TO transistor (as an element in the “current mirror” circuit block) in each the CI-aCAM circuits 520a-520f that receives the current signal output from a column of the DPE 510. Stated another way, each respective current signal that is output from each of the columns 516a-516f of the DPE circuit 510 (corresponding to output lines 511a-511f of the DPE circuit 510) represents an element of the vector result from the matrix vector multiplication that is performed by the DPE circuit 510. Thus, each of the CI-aCAMs circuits 520a-520f receives current as an input signal (from a corresponding one of the output lines 511a-511f) that corresponds to an element associated with the results of the matrix vector multiplication performed by the DPE circuit 510. Particularly, the CI-aCAM array circuit 520 can perform a respective search operation for each input signal that is has received (or each element of the vector result from the matrix vector multiplication). Consequently, each output signal from one of the individual CI-aCAMs circuits 520a-520f conveys the result of a search operation (e.g., match or mismatch) performed on the corresponding element it is has received (output from the corresponding column 516a-516f of the DPE circuit 510). This relationship between the output current from each column of the memristor crossbar of the DPE 510, and the input current of each of the CI-aCAM circuits 520a-520f can be described mathematically as:

$${I}_{j} = {\sum }_{i = 0}^{N} {V}_{i} {G}_{i j}$$

where Iⱼ is the current that flows directly into the TO transistor of each of the CI-aCAM circuits.

Particularly, FIG. 5 prominently illustrates the circuitry for at least one of the CI-aCAM circuits, namely CI-aCAM circuit 520a. The CI-aCAM circuit 520a is shown to be coupled to the output 511a corresponding to a first column of the matrix, or memristor crossbar, for the DPE 510. Thus, FIG. 5 shows that the output line from output 511a of the DPE 520 is coupled to an input line of the CI-aCAM circuit 520a (e.g., data input line as referred to in reference to FIG. 4) that is directly coupled to the drain terminal of the TO transistor 522a, thereby allowing the current signal that is output from this row of the DPE 510 to flow directly into the TO transistor 522a of the CI-aCAM circuit 520a. Although not shown in FIG. 5, it can be assumed that the remaining CI-aCAM circuits 520b-520f also have this configuration, having their respective input lines (or data input lines) and TO transistors coupled to the corresponding output column from the memristor crossbar of the DPE 510 in a manner that allows the current that propagates from each of the output 511a-511f (from each column of the DPE 510) to be the current that is directly input into each correspondingly coupled CI-aCAM circuit 520a-520f.

Accordingly, this configuration may utilize an H×N array of CI-aCAM circuits for a corresponding M×N matrix of memristors in the memristor crossbar, where the number of CI-aCAM circuits included in each row of the array (e.g., number of columns of the CI-aCAM array 250) equals the number of columns in the memristor crossbar matrix of the DPE 510. As seen in the example of FIG. 5, the CI-aCAM array 520 section of the DPE-aCAM circuit 500 is structured as a 2×6 array of CI-aCAM circuits 520a-520f to accommodate the 6×6 memristor crossbar matrix of the DPE 510 section of the DPE-aCAM circuit 500, where each of the CI-aCAM circuits 520a-520f (within a row) corresponds to a respective column of the memristor crossbar matrix of the DPE 510. In the configuration of FIG. 5, each of the two rows CI-aCAM circuits 520a-520f in the CI-aCAM array 520 can have an independent output. However, in an embodiment, a single CI-aCAM circuit can be used by multiple rows and/or columns of the memristor crossbar matrix of the DPE 510, which can reduce the scaling impact and overhead of the implementation of the DPE-aCAM circuit 500.

Consequently, the disclosed DPE-aCAM circuit 500 enables the efficient combination of two core analog compute circuits for matrix multiplication (i.e., functionality implemented by the DPE 520) and search operations (i.e., functionality implemented by the CI-aCAM array 520). An example of an application for the disclosed DPE-aCAM circuit 500 that is in the realm of deep learning is employing the circuitry for MANNs. Furthermore, the unique structure and functionality of the DPE-aCAM circuit 500 enables a wide-range of complex algorithms that can be accelerated end-to-end by combining its distinct DPE and aCAM operations. For instance, the architecture of the disclosed DPE-aCAM circuit 500, where the DPE is cascaded with CI-aCAMs, can be leveraged to implement a MANN where similarity measures can be performed by the CI-aCAM circuitry after neural network evaluations are carried out by the DPE circuitry. In another example, the DPE-aCAM circuit 500 could implement various feature extraction layers (via neural network fully connected layers) using the DPE circuitry, and then apply the extracted feature vector as searchable input to the CI-aCAM circuitry. Moreover, by leveraging the distinct capabilities of the disclosed CI-aCAM, a highly resource-consuming conversion step (e.g., converting current output to voltage input) that would be associated with integrating DPEs with voltage-based aCAMs is removed. Thus, the disclosed DPE-aCAM circuit 500 realizes an improved efficiency in neural network processing (e.g., by eliminating processing dedicated to a large number of extraneous conversions) that would otherwise be slowed-down by cumbersome overhead. Additionally, the disclosed structure of the DPE-aCAM circuit 500 eliminates the need for supplemental circuitry, such as the integration of several transimpedance amplifiers between the DPE and the voltage-based aCAMs, that would be required to support current-to-voltage conversions (and analog-to-digital conversions) in such a configuration. Limiting computational and hardware overhead is key for advancing neural network and deep learning technology, as these problems can scale-up in a manner that impacts performance and costs as the complexities of the algorithms increase. Consequently, by achieving significant reductions in power consumption and circuit area overhead, the disclosed DPE-aCAM circuit 500 may serve as a building block as advanced implementations for neural networks and other computing intensive applications continue to emerge.

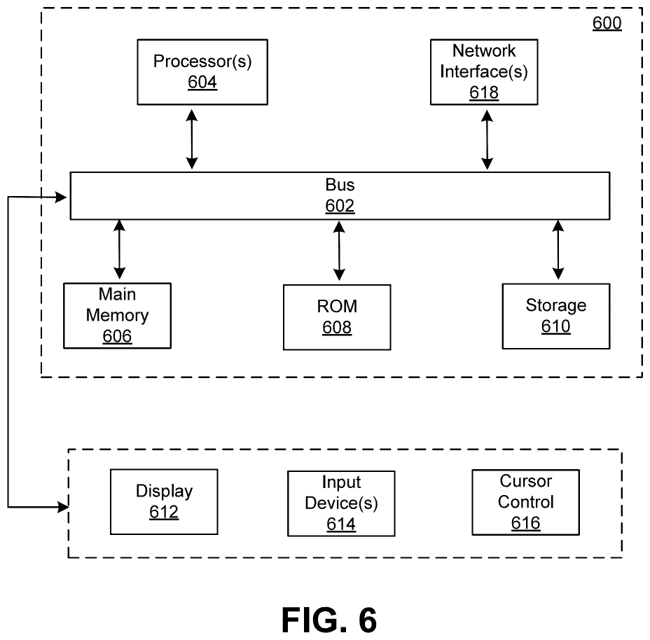

FIG. 6 depicts a block diagram of an example computer system 600 in which various embodiments described herein may be implemented. For example, the computer system 600 may implement the aforementioned DPE-aCAM circuitry 500 (shown in FIG. 5) which employs the disclosed CI-aCAM circuitry 400 (shown in FIG. 4) to implement complex computation techniques, such as neural networks computing. The computer system 600 includes a bus 602 or other communication mechanism for communicating information, one or more hardware processors 604 coupled with bus 602 for processing information. Hardware processor(s) 604 may be, for example, one or more general purpose microprocessors.

The computer system 600 also includes a main memory 606, such as a random-access memory (RAM), cache and/or other dynamic storage devices, coupled to bus 602 for storing information and instructions to be executed by processor 604. Main memory 606 also may be used for storing temporary variables or other intermediate information during execution of instructions to be executed by processor 604. Such instructions, when stored in storage media accessible to processor 604, render computer system 600 into a special-purpose machine that is customized to perform the operations specified in the instructions.

The computer system 600 further includes a read only memory (ROM) 608 or other static storage device coupled to bus 602 for storing static information and instructions for processor 604. A storage device 610, such as a magnetic disk, optical disk, or USB thumb drive (Flash drive), etc., is provided and coupled to bus 602 for storing information and instructions.

The computer system 600 may be coupled via bus 602 to a display 612, such as a liquid crystal display (LCD) (or touch screen), for displaying information to a computer user. An input device 614, including alphanumeric and other keys, is coupled to bus 602 for communicating information and command selections to processor 604. Another type of user input device is cursor control 816, such as a mouse, a trackball, or cursor direction keys for communicating direction information and command selections to processor 604 and for controlling cursor movement on display 612. In some embodiments, the same direction information and command selections as cursor control may be implemented via receiving touches on a touch screen without a cursor.

The computing system 600 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

The computer system 600 may implement the techniques described herein using customized hard-wired logic, one or more ASICs or FPGAs, firmware and/or program logic which in combination with the computer system causes or programs computer system 600 to be a special-purpose machine. According to one embodiment, the techniques herein are performed by computer system 600 in response to processor(s) 604 executing one or more sequences of one or more instructions contained in main memory 606. Such instructions may be read into main memory 606 from another storage medium, such as storage device 610. Execution of the sequences of instructions contained in main memory 606 causes processor(s) 604 to perform the process steps described herein. In alternative embodiments, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 810. Volatile media includes dynamic memory, such as main memory 606. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 602. Transmission media can also take the form of acoustic or light waves, such as those generated during radio-wave and infra-red data communications.

The computer system 600 also includes a communication interface 618 coupled to bus 602. Network interface 618 provides a two-way data communication coupling to one or more network links that are connected to one or more local networks. For example, communication interface 618 may be an integrated services digital network (ISDN) card, cable modem, satellite modem, or a modem to provide a data communication connection to a corresponding type of telephone line. As another example, network interface 618 may be a local area network (LAN) card to provide a data communication connection to a compatible LAN (or WAN component to communicated with a WAN). Wireless links may also be implemented. In any such implementation, network interface 618 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world-wide packet data communication network now commonly referred to as the “Internet.” Local network and Internet both use electrical, electromagnetic or optical signals that carry digital data streams. The signals through the various networks and the signals on network link and through communication interface 818, which carry the digital data to and from computer system 600, are example forms of transmission media.

The computer system 600 can send messages and receive data, including program code, through the network(s), network link and communication interface 618. In the Internet example, a server might transmit a requested code for an application program through the Internet, the ISP, the local network and the communication interface 618.

The received code may be executed by processor 604 as it is received, and/or stored in storage device 610, or other non-volatile storage for later execution.

As used herein, a circuit might be implemented utilizing any form of hardware, software, or a combination thereof. For example, one or more processors, controllers, ASICs, PLAs, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 600.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

What is claimed is:

1. A circuit, comprising:
a match line;
an input line receiving an input signal;
a first transistor coupled to the input line, wherein the transistor receives a current signal propagating the input line as the input signal; and
circuitry for receiving a mirrored current from the transistor and outputting a signal on the match line when the input signal generates a match based on the input signal.

2. The circuit of claim 1, wherein the circuitry comprises a second transistor coupled to the match line and having a gate voltage associated with the second transistor.

3. The circuit of claim 1, wherein the match comprises the match line having a charge, the current signal comprising a value within the range of 25 μA and 75 μA, and the gate voltage associated with the second transistor comprising a value within the range of 0 V and 0.05 V.

4. The circuit of claim 1, wherein the circuitry comprises a first memristor and a second memristor.

5. The circuit of claim 4, wherein the match comprises the match line having a charge, and the input signal being within a range of analog values that are set by the first memristor and the second memristor.

6. The circuit of claim 1, wherein a mismatch comprises the match line being discharged, the current signal comprising a value within the range of within the range of 0.05 μA and 0.5 μA, and the gate voltage associated with the second transistor comprising a value within the range of 1 V and 10 V.

7. The circuit of claim 6, wherein the circuitry outputs a signal that has been discharged on the match line when the input signal generates a mismatch based on the input signal.

8. The circuit of claim 1, wherein the input line is coupled to an output line of a dot product engine (DPE) circuit receiving the current signal as output from the DPE circuit.

9. A circuit, comprising:
a dot product engine (DPE) circuit, the DPE circuit performing matrix multiplication; and
a current-input analog content addressable memory (CI-aCAM) array circuit coupled to the DPE, the CI-aCAM array circuit performing an aCAM search based on the matrix multiplication of the DPE circuit.

10. The circuit of claim 9, wherein the DPE circuit comprises a memristor crossbar matrix of a plurality of resistive memory elements arranged in rows and columns.

11. The circuit of claim 10, wherein the plurality of resistive memory elements determines matrix multiplication values, and further wherein the memristor crossbar matrix comprises a plurality of columns of output lines to collect all currents output from the resistive memory elements, the collected currents on each column equaling a corresponding matrix multiplication value.

12. The circuit of claim 11, wherein the CI-aCAM array comprises a plurality of CI-aCAM circuits.

13. The circuit of claim 12, wherein each of the plurality of CI-aCAM circuits is coupled to a column of the plurality of columns of the memristor crossbar matrix.

14. The circuit of claim 13, wherein each of the plurality of CI-aCAM circuits comprises an input line coupled to a transistor.

15. The circuit of claim 14, wherein each input line of the plurality of CI-aCAM circuits receives the collected current on each correspondingly coupled column of output lines of the memristor crossbar matrix.

16. A method comprising:
performing, by a circuit block, matrix multiplication;
outputting, by the circuit block, current signals conveying results of the matrix multiplication; receiving, by an additional circuit block, the current signals conveying the results of the matrix multiplication as input signals, wherein each of the input signals are associated with the results of the matrix multiplication; and
outputting, by the additional circuit block, output signals corresponding to search operations performed based on the input signals associated with the results of the matrix multiplication.

17. The method of claim 16, wherein the circuit block comprises a dot product engine (DPE) circuit and the additional circuit block comprises a current-input analog content addressable memory (CI-aCAM) array circuit.

18. The method of claim 17, wherein the (DPE) circuit comprises a memristor crossbar matrix having columns and the CI-aCAM array circuit comprises a plurality of individual CI-aCAM circuits, each individual CI-aCAM circuit coupled to a corresponding one of the columns of the memristor crossbar matrix.

19. The method of claim 18, comprising:
outputting, by each column of the memristor crossbar matrix, a current signal conveying an element associated with the results of matrix multiplication performed by the DPE circuit;
receiving, by each of the plurality of individual CI-aCAMs circuits, the current signal from the corresponding column of the memristor crossbar matrix as an input signal, wherein each input signal corresponds to the element associated with the results of the matrix multiplication from the corresponding column of the memristor crossbar matrix.

20. The method of claim 19, wherein outputting the output signals comprises:
performing, by each of the plurality of individual CI-aCAMs circuits, a search operation on the corresponding input signal received; and
outputting, by each of the plurality of individual CI-aCAMs circuits, an output signal conveying a match from the search operation based on the corresponding element associated with the results of the matrix multiplication performed by the DPE circuit.
